(19) United States
(12) Patent Application Publication
(10) Pub. No.: US 2022/0389189 A1
(43) Pub. Date: Dec. 8, 2022

(54) RESIN COMPOSITION, PREPREG, RESIN-EQUIPPED FILM, RESIN-EQUIPPED METAL FOIL, METAL-CLADDED LAYERED SHEET, AND WIRING BOARD

(71) Applicant: PANASONIC INTELLECTUAL PROPERTY MANAGEMENT CO., LTD., Osaka (JP)

(72) Inventors: Mikio SATO, Fukushima (JP); Yuki KITAI, Osaka (JP); Yasunori HOSHINO, Hyogo (JP)

(73) Assignee: PANASONIC INTELLECTUAL PROPERTY MANAGEMENT CO., LTD., Osaka (JP)

(21) Appl. No.: 17/763,105

(22) PCT Filed: Sep. 3, 2020
(86) PCT No.: PCT/JP2020/033365

§ 371 Date: Mar. 23, 2022

(30) Foreign Application Priority Data
Sep. 27, 2019 (JP) 2019-176538

(51) Int. Cl. C08K 3/38; C08K 5/3492; C08K 3/26; C08K 9/06; C08K 3/22; C08J 5/24; H05K 1/03

(52) U.S. Cl. CPC C08K 3/38; C08K 5/34924; C08K 3/26; C08K 9/06; C08K 3/22; C08J 5/244; H05K 1/0373; H05K 1/0366; C08K 2003/385; C08J 2371/12; C08K 2003/267; C08K 2003/2227; H05K 2201/0209

(57) ABSTRACT

An aspect of the present invention is a resin composition, which contains a polyphenylene ether compound, a curing agent, boron nitride, and an inorganic filler other than the boron nitride, in which the content of boron nitride is 15 to 70 parts by volume with respect to 100 parts by volume of the sum of the polyphenylene ether compound and the curing agent.

### TECHNICAL FIELD

The present invention relates to a resin composition, a prepreg, a film with resin, a metal foil with resin, a metal-clad laminate, and a wiring board.

### BACKGROUND ART

As the information processing quantity by various kinds of electronic equipment increases, mounting technologies such as high integration of semiconductor devices to be mounted, densification of wiring, and multilayering are progressing. In addition, wiring boards to be used in various kinds of electronic equipment are required to be, for example, high-frequency compatible wiring boards such as a millimeter-wave radar board for in-vehicle use. Substrate materials for forming insulating layers of wiring boards to be used in various kinds of electronic equipment are required to have a low dielectric constant and a low dielectric loss tangent in order to increase the signal transmission speed and to decrease the signal transmission loss.

It is known that polyphenylene ether exhibits excellent low dielectric properties such as a low dielectric constant and a low dielectric loss tangent and exhibits excellent low dielectric properties such as a low dielectric constant and a low dielectric loss tangent even in a high frequency band (high frequency region) from the MHz band to the GHz band. For this reason, it has been investigated that polyphenylene ether is used, for example, as a high frequency molding material. More specifically, polyphenylene ether is preferably used as a substrate material for forming an insulating layer of a wiring board to be equipped in electronic equipment utilizing a high frequency band.

Wiring boards are also required to exhibit high heat dissipation and high heat resistance. For example, in a wiring board on which electronic components and the like are mounted at high density, the amount of heat generated per unit area increases. In order to reduce the occurrence of troubles due to the increase in the amount of heat generated, it is required to enhance the heat dissipation, heat resistance, and the like of wiring boards. In order to enhance the heat dissipation of a wiring board, it is conceivable to increase the thermal conductivity of the wiring board by containing an inorganic filler in the substrate material for forming the insulating layer of the wiring board. It is considered that the heat resistance, such as moisture absorption heat resistance, of the wiring board can be enhanced by containing an inorganic filler in the substrate material for forming the insulating layer of the wiring board. Examples of such substrate materials include the resin composition described in Patent Literature 1.

Patent Literature 1 describes a flame retardant curable resin composition containing a predetermined polyfunctional vinyl aromatic copolymer, a phosphorus-nitrogen-based flame retardant, and an inorganic filler having an average particle size of 0.001 to 6 μm in predetermined amounts, respectively. According to Patent Literature 1, it is disclosed that a thin molded product or a cured product also exhibits a high degree of flatness, flowability, flame retardancy, favorable appearance, molding processability, curing properties, dielectric properties, heat resistance, and heat resistant hydrolyzability.

There is an increasing demand for mounting of electronic components and the like on wiring boards in higher density. Hence, in order to further enhance the heat dissipation of wiring boards, it is required to further increase the thermal conductivity of wiring boards and higher heat resistance is also required.

### CITATION LIST

### Patent Literature

Patent Literature 1: JP 2007-262191 A

### SUMMARY OF INVENTION

The present invention has been made in view of such circumstances, and an object thereof is to provide a resin composition, which provides a cured product exhibiting low dielectric properties, a high thermal conductivity, and high heat resistance. Another object of the present invention is to provide a prepreg, a film with resin, a metal foil with resin, a metal-clad laminate, and a wiring board which are obtained using the resin composition.

An aspect of the present invention is a resin composition containing a polyphenylene ether compound, a curing agent, boron nitride, and an inorganic filler other than boron nitride, in which the content of boron nitride is 15 to 70 parts by volume with respect to 100 parts by volume of a sum of the polyphenylene ether compound and the curing agent.

### BRIEF DESCRIPTION OF DRAWINGS

FIG. 1 is a schematic sectional view illustrating an example of a prepreg according to an embodiment of the present invention.

FIG. 2 is a schematic sectional view illustrating an example of a metal-clad laminate according to an embodiment of the present invention.

FIG. 3 is a schematic sectional view illustrating an example of a wiring board according to an embodiment of the present invention.

FIG. 4 is a schematic sectional view illustrating an example of a metal foil with resin according to an embodiment of the present invention.

FIG. 5 is a schematic sectional view illustrating an example of a film with resin according to an embodiment of the present invention.

### DESCRIPTION OF EMBODIMENTS

According to the studies by the present inventors, it has been found out that there is a tendency that the thermal conductivity cannot be sufficiently increased even when the substrate material for forming the insulating layer of a wiring board is highly-filled with, for example, silica as an inorganic filler. In addition, there is a tendency that low dielectric properties such as low dielectric constant cannot be maintained when, for example, magnesium oxide is highly-filled as an inorganic filler. From these facts, it has been found out that a conventional resin composition does not provide, for example, a cured product which has a high thermal conductivity such as 1 W/m·K or more and exhibits sufficiently low dielectric properties such as dielectric constant and sufficiently high heat resistance such as moisture absorption heat resistance (PCT solder heat resistance). Even when a maleimide compound is used to decrease the dielectric properties, there is a tendency that the coefficient of moisture absorption increases and the PCT solder heat resistance decreases. When only a maleimide compound is used, there is a tendency that a resin composition, which provides a cured product exhibiting low dielectric properties, a high thermal conductivity, and high heat resistance, is not obtained.

Hence, the present inventors have conducted studies on the use of boron nitride exhibiting high thermal conductivity as an inorganic filler contained in the substrate material for forming the insulating layer of a wiring board in order to increase the thermal conductivity of the wiring board. According to the studies by the present inventors, it has been found out that troubles occur such that heat resistance such as PCT solder heat resistance cannot be sufficiently enhanced when it is attempted to achieve the required thermal conductivity by using only boron nitride as an inorganic filler. From this fact, the present inventors have focused on the composition of inorganic filler and further conducted studies to find out that a resin composition, which provides a cured product exhibiting low dielectric properties, a high thermal conductivity, and high heat resistance, is obtained by using not only boron nitride but also an inorganic filler other than the boron nitride and further adjusting the content of the boron nitride.

As a result of extensive studies on the facts above, the present inventors have found out that the object to provide a resin composition which provides a cured product exhibiting low dielectric properties, a high thermal conductivity, and high heat resistance is achieved by the following present invention.

Hereinafter, embodiments according to the present invention will be described, but the present invention is not limited thereto.

The resin composition according to the present embodiment contains a polyphenylene ether compound, a curing agent, boron nitride, and an inorganic filler other than boron nitride. The content of the boron nitride is 15 to 70 parts by volume with respect to 100 parts by volume of the sum of the polyphenylene ether compound and the curing agent.

First, it is considered that a cured product which maintains the excellent low dielectric properties of polyphenylene ether is obtained by curing the polyphenylene ether compound together with the curing agent even when boron nitride and an inorganic filler other than the boron nitride are contained in the resin composition. It is considered that a resin composition providing a cured product having a high thermal conductivity is obtained by containing boron nitride exhibiting high thermal conductivity in the resin composition so as to be within the above content range. It is considered that an inorganic filler other than the boron nitride is contained so as to exist between the boron nitrides by containing not only the boron nitride but also the inorganic filler other than the boron nitride in the resin composition. For this reason, it is considered that the resin composition provides a cured product exhibiting high heat resistance as well as a high thermal conductivity. From the above facts, it is considered that the resin composition provides a cured product exhibiting low dielectric properties, a high thermal conductivity, and high heat resistance.

(Polyphenylene Ether Compound)

The polyphenylene ether compound is not particularly limited as long as it can form a cured product together with the curing agent. Examples of the polyphenylene ether compound include a polyphenylene ether compound having an unsaturated double bond in the molecule.

Examples of the polyphenylene ether compound having an unsaturated double bond in the molecule include a polyphenylene ether compound having a substituent having an unsaturated double bond at the molecular terminal such as a modified polyphenylene ether compound of which the terminal is modified with a substituent having an unsaturated double bond.

The substituent having an unsaturated double bond is not particularly limited. Examples of the substituent include a substituent represented by the following Formula (1) and a substituent represented by the following Formula (2). In other words, the polyphenylene ether compound preferably includes a polyphenylene ether compound having at least one of a group represented by the following Formula (1) and a group represented by the following Formula (2) in the molecule.

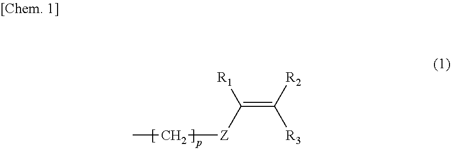

In Formula (1), p represents 0 to 10. Z represents an arylene group. R₁ to R₃ are independent of each other. In other words, R₁ to R₃ may be the same group as or different groups from each other. R₁ to R₃ represent a hydrogen atom or an alkyl group.

In a case where p in Formula (1) is 0, it indicates that Z is directly bonded to the terminal of polyphenylene ether.

This arylene group is not particularly limited. Examples of this arylene group include a monocyclic aromatic group such as a phenylene group, and a polycyclic aromatic group in which the aromatic is not a single ring but a polycyclic aromatic such as a naphthalene ring. This arylene group also includes a derivative in which a hydrogen atom bonded to an aromatic ring is substituted with a functional group such as an alkenyl group, an alkynyl group, a formyl group, an alkylcarbonyl group, an alkenylcarbonyl group, or an alkynylcarbonyl group. In addition, the alkyl group is not particularly limited and is, for example, preferably an alkyl group having 1 to 18 carbon atoms and more preferably an alkyl group having 1 to 10 carbon atoms. Specific examples thereof include a methyl group, an ethyl group, a propyl group, a hexyl group, and a decyl group.

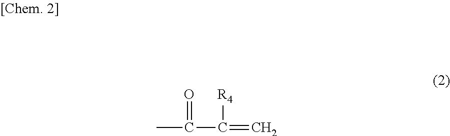

In Formula (2), R₄ represents a hydrogen atom or an alkyl group. The alkyl group is not particularly limited and is, for example, preferably an alkyl group having 1 to 18 carbon atoms and more preferably an alkyl group having 1 to 10 carbon atoms. Specific examples thereof include a methyl group, an ethyl group, a propyl group, a hexyl group, and a decyl group.

Preferred specific examples of the substituent represented by Formula (1) include, for example, a substituent having a vinylbenzyl group. Examples of the substituent having a vinylbenzyl group include a substituent represented by the following Formula (3). Examples of the substituent represented by Formula (2) include an acryloyl group and a methacryloyl group.

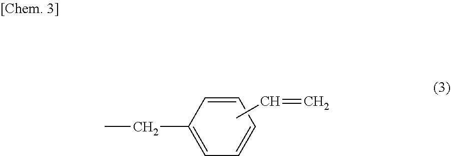

More specific examples of the substituent include vinylbenzyl groups (ethenylbenzyl groups) such as an o-ethenylbenzyl group, a p-ethenylbenzyl group, and an m-ethenylbenzyl group, a vinylphenyl group, an acryloyl group, and a methacryloyl group. The polyphenylene ether compound may have one kind of substituent or two or more kinds of substituents as the substituent. The polyphenylene ether compound may have, for example, any of an o-ethenylbenzyl group, a p-ethenylbenzyl group, and an m-ethenylbenzyl group, or two or three kinds thereof.

The polyphenylene ether compound has a polyphenylene ether chain in the molecule and preferably has, for example, a repeating unit represented by the following Formula (4) in the molecule.

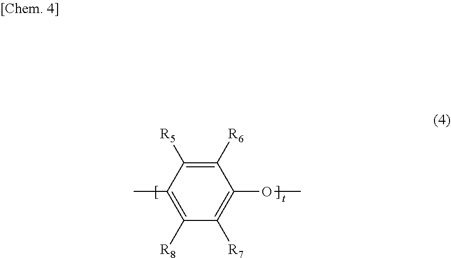

In Formula (4), t represents 1 to 50. R₅ to R₈ are independent of each other. In other words, R₅ to R₈ may be the same group as or different groups from each other. R₅ to R₈ represent a hydrogen atom, an alkyl group, an alkenyl group, an alkynyl group, a formyl group, an alkylcarbonyl group, an alkenylcarbonyl group, or an alkynylcarbonyl group. Among these, a hydrogen atom and an alkyl group are preferable.

Specific examples of the respective functional groups mentioned in R₅ to R₈ include the following.

The alkyl group is not particularly limited and is, for example, preferably an alkyl group having 1 to 18 carbon atoms and more preferably an alkyl group having 1 to 10 carbon atoms. Specific examples thereof include a methyl group, an ethyl group, a propyl group, a hexyl group, and a decyl group.

The alkenyl group is not particularly limited and is, for example, preferably an alkenyl group having 2 to 18 carbon atoms and more preferably an alkenyl group having 2 to 10 carbon atoms. Specific examples thereof include a vinyl group, an allyl group, and a 3-butenyl group.

The alkynyl group is not particularly limited and is, for example, preferably an alkynyl group having 2 to 18 carbon atoms and more preferably an alkynyl group having 2 to 10 carbon atoms. Specific examples thereof include an ethynyl group and a prop-2-yn-1-yl group (propargyl group).

The alkylcarbonyl group is not particularly limited as long as it is a carbonyl group substituted with an alkyl group and is, for example, preferably an alkylcarbonyl group having 2 to 18 carbon atoms and more preferably an alkylcarbonyl group having 2 to 10 carbon atoms. Specific examples thereof include an acetyl group, a propionyl group, a butyryl group, an isobutyryl group, a pivaloyl group, a hexanoyl group, an octanoyl group, and a cyclohexylcarbonyl group.

The alkenylcarbonyl group is not particularly limited as long as it is a carbonyl group substituted with an alkenyl group and is, for example, preferably an alkenylcarbonyl group having 3 to 18 carbon atoms and more preferably an alkenylcarbonyl group having 3 to 10 carbon atoms. Specific examples thereof include an acryloyl group, a methacryloyl group, and a crotonoyl group.

The alkynylcarbonyl group is not particularly limited as long as it is a carbonyl group substituted with an alkynyl group and is, for example, preferably an alkynylcarbonyl group having 3 to 18 carbon atoms and more preferably an alkynylcarbonyl group having 3 to 10 carbon atoms. Specific examples thereof include a propioloyl group.

The weight average molecular weight (Mw) of the polyphenylene ether compound is not particularly limited. Specifically, the weight average molecular weight is preferably 500 to 5000, more preferably 800 to 4000, and still more preferably 1000 to 3000. Here, the weight average molecular weight may be measured by a general molecular weight measurement method, and specific examples thereof include a value measured by gel permeation chromatography (GPC). In a case where the polyphenylene ether compound has a repeating unit represented by Formula (4) in the molecule, t is preferably a numerical value so that the weight average molecular weight of the polyphenylene ether compound is in such a range. Specifically, t is preferably 1 to 50.

When the weight average molecular weight of the polyphenylene ether compound is in such a range, the polyphenylene ether compound exhibits the excellent low dielectric properties of polyphenylene ether and not only imparts superior heat resistance to the cured product but also exhibits excellent moldability. This is considered to be due to the following. When the weight average molecular weight of ordinary polyphenylene ether is in such a range, the heat resistance of the cured product tends to decrease since the molecular weight is relatively low. With regard to this point, since the polyphenylene ether compound according to the present embodiment has one or more unsaturated double bonds at the terminal, it is considered that a cured product exhibiting sufficiently high heat resistance is obtained. When the weight average molecular weight of the polyphenylene ether compound is in such a range, the polyphenylene ether compound has a relatively low molecular weight and is thus considered to exhibit excellent moldability. Hence, it is considered that such a polyphenylene ether compound not only imparts superior heat resistance to the cured product but also exhibits excellent moldability.

In the polyphenylene ether compound, the average number of the substituents (number of terminal functional groups) at the molecule terminal per one molecule of the polyphenylene ether compound is not particularly limited. Specifically, the average number is preferably 1 to 5, more preferably 1 to 3, and still more preferably 1.5 to 3. When the number of terminal functional groups is too small, sufficient heat resistance of the cured product tends to be hardly attained. When the number of terminal functional groups is too large, the reactivity is too high and, for example, troubles such as deterioration in the storage stability of the resin composition or deterioration in the fluidity of the resin composition may occur. In other words, when such a polyphenylene ether compound is used, for example, molding defects such as generation of voids at the time of multilayer molding occur by insufficient fluidity and the like and a problem of moldability that a highly reliable printed wiring board is hardly obtained may occur.

The number of terminal functional groups in the polyphenylene ether compound includes a numerical value expressing the average value of the substituents per one molecule of all the polyphenylene ether compounds present in 1 mole of the polyphenylene ether compound. This number of terminal functional groups can be determined by, for example, measuring the number of hydroxyl groups remaining in the obtained polyphenylene ether compound and calculating the number of hydroxyl groups decreased from the number of hydroxyl groups in the polyphenylene ether before having (before being modified with) the substituent. The number of hydroxyl groups decreased from the number of hydroxyl groups in the polyphenylene ether before being modified is the number of terminal functional groups. Moreover, with regard to the method for measuring the number of hydroxyl groups remaining in the polyphenylene ether compound, the number of hydroxyl groups can be determined by adding a quaternary ammonium salt (tetraethylammonium hydroxide) to be associated with a hydroxyl group to a solution of the polyphenylene ether compound and measuring the UV absorbance of the mixed solution.

The intrinsic viscosity of the polyphenylene ether compound is not particularly limited. Specifically, the intrinsic viscosity is preferably 0.03 to 0.12 dl/g, more preferably 0.04 to 0.11 dl/g, still more preferably 0.06 to 0.095 dl/g. When the intrinsic viscosity is too low, the molecular weight tends to be low and low dielectric properties such as a low dielectric constant and a low dielectric loss tangent tend to be hardly attained. When the intrinsic viscosity is too high, the viscosity is high, sufficient fluidity is not attained, and the moldability of the cured product tends to decrease. Hence, when the intrinsic viscosity of the polyphenylene ether compound is in the above range, excellent heat resistance and moldability of the cured product can be realized.

Note that the intrinsic viscosity here is an intrinsic viscosity measured in methylene chloride at 25° C. and more specifically is, for example, a value attained by measuring the intrinsic viscosity of a methylene chloride solution (liquid temperature: 25° C.) at 0.18 g/45 ml using a viscometer. Examples of the viscometer include AVS500 Visco System manufactured by SCHOTT Instruments GmbH.

Examples of the polyphenylene ether compound include a polyphenylene ether compound represented by the following Formula (5) and a polyphenylene ether compound represented by the following Formula (6). As the polyphenylene ether compound, these polyphenylene ether compounds may be used singly or these two kinds of polyphenylene ether compounds may be used in combination.

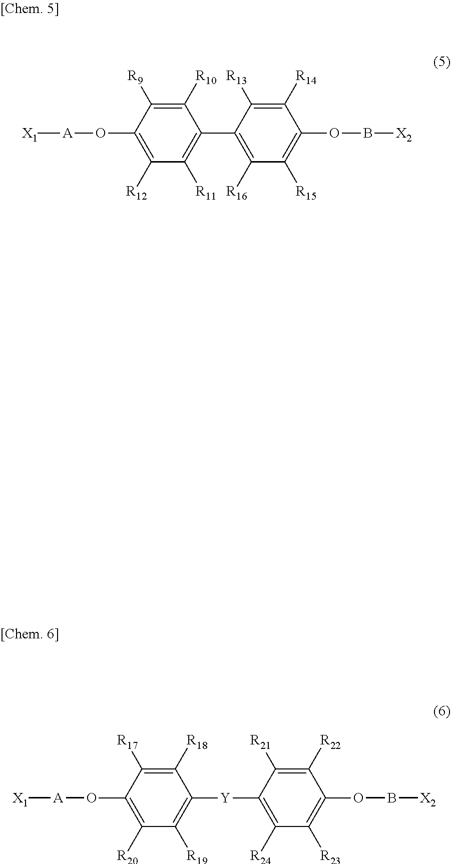

In Formulas (5) and (6), R₉ to R₁₆ and R₁₇ to R₂₄ each independently represent a hydrogen atom, an alkyl group, an alkenyl group, an alkynyl group, a formyl group, an alkylcarbonyl group, an alkenylcarbonyl group, or an alkynylcarbonyl group. X₁ and X₂ each independently represent a substituent having a carbon-carbon unsaturated double bond. A and B represent a repeating unit represented by the following Formula (7) and a repeating unit represented by the following Formula (8), respectively. In Formula (6), Y represents a linear, branched, or cyclic hydrocarbon having 20 or less carbon atoms

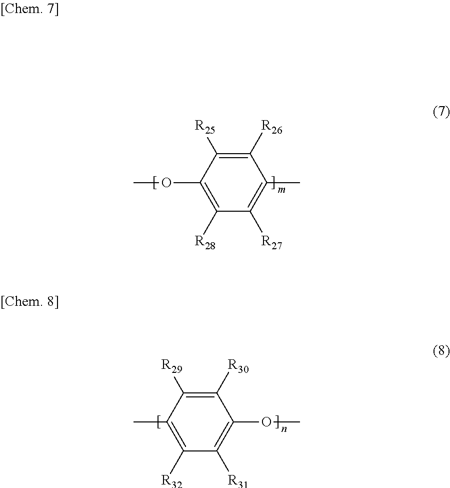

In Formulas (7) and (8), in and n each represent 0 to 20. R₂₅ to R₂₈ and R₂₉ to R₃₂ each independently represent a hydrogen atom, an alkyl group, an alkenyl group, an alkynyl group, a formyl group, an alkylcarbonyl group, an alkenylcarbonyl group, or an alkynylcarbonyl group.

The polyphenylene ether compound represented by Formula (5) and the polyphenylene ether compound represented by Formula (6) are not particularly limited as long as they are compounds satisfying the configuration. Specifically, in Formulas (5) and (6), R₉ to R₁₆ and R₁₇ to R₂₄ are independent of each other as described above. In other words, R₉ to R₁₆ and R₁₇ to R₂₄ may be the same group as or different groups from each other. R₉ to R₁₆ and R₁₇ to R₂₄ represent a hydrogen atom, an alkyl group, an alkenyl group, an alkynyl group, a formyl group, an alkylcarbonyl group, an alkenylcarbonyl group, or an alkynylcarbonyl group. Among these, a hydrogen atom and an alkyl group are preferable.

In Formulas (7) and (8), m and n each preferably represent 0 to 20 as described above. In addition, it is preferable that in and n represent numerical values so that the sum of in and n is 1 to 30. Hence, it is more preferable that in represents 0 to 20, n represents 0 to 20, and the sum of in and n represents 1 to 30. R₂₅ to R₂₈ and R₂₉ to R₃₂ are independent of each other. In other words, R₂₅ to R₂₈ and R₂₉ to R₃₂ may be the same group as or different groups from each other. R₂₅ to R₂₈ and R₂₉ to R₃₂ represent a hydrogen atom, an alkyl group, an alkenyl group, an alkynyl group, a formyl group, an alkylcarbonyl group, an alkenylcarbonyl group, or an alkynylcarbonyl group. Among these, a hydrogen atom and an alkyl group are preferable.

R₉ to R₃₂ are the same as R₅ to R₈ in Formula (4).

In Formula (6), Y represents a linear, branched, or cyclic hydrocarbon having 20 or less carbon atoms as described above. Examples of Y include a group represented by the following Formula (9).

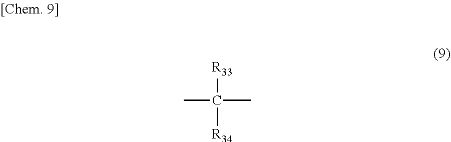

In Formula (9), R₃₃ and R₃₄ each independently represent a hydrogen atom or an alkyl group. Examples of the alkyl group include a methyl group. Examples of the group represented by Formula (9) include a methylene group, a methylmethylene group, and a dimethylmethylene group. Among these, a dimethylmethylene group is preferable.

In Formulas (5) and (6), X₁ and X₂ are each independently the group represented by Formula (1) or the group represented by Formula (2). In the polyphenylene ether compound represented by Formula (5) and the polyphenylene ether compound represented by Formula (6), X₁ and X₂ may be the same group as or different groups from each other.

More specific examples of the polyphenylene ether compound represented by Formula (5) include a polyphenylene ether compound represented by the following Formula (10).

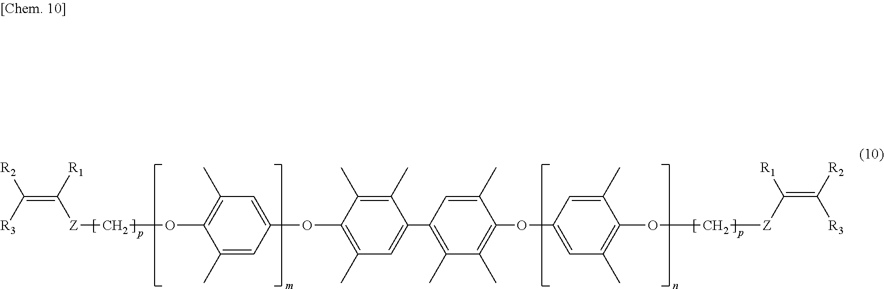

More specific examples of the polyphenylene ether compound represented by Formula (6) include a polyphenylene ether compound represented by the following Formula (11) and a polyphenylene ether compound represented by the following Formula (12).

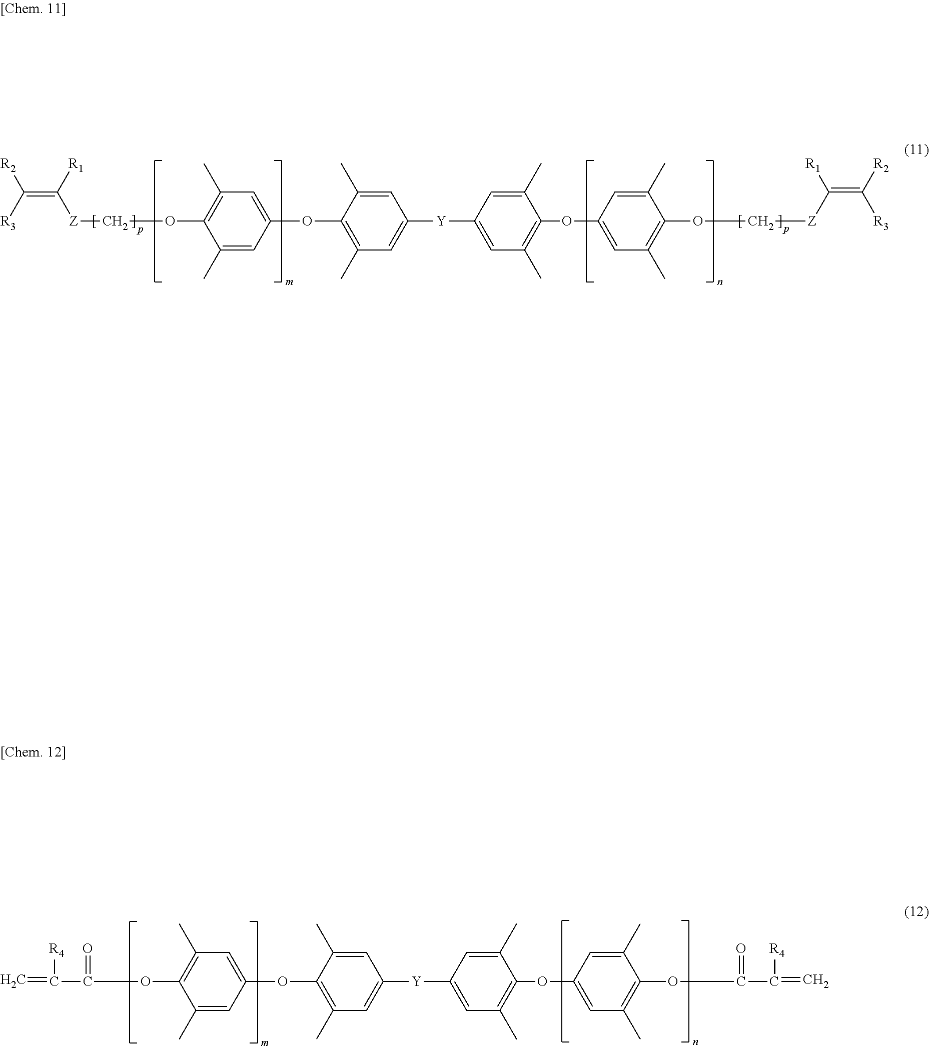

In Formulas (10) to (12), m and n are the same as m and n in Formulas (7) and (8). In Formulas (10) and (11), R₁ to R₃, p, and Z are the same as R₁ to R₃, p, and Z in Formula (1). In Formulas (11) and (12), Y is the same as Y in Formula (6). In Formula (12), R₄ is the same as R₁ in Formula (2).

The method for synthesizing the polyphenylene ether compound to be used in the present embodiment is not particularly limited as long as a polyphenylene ether compound having an unsaturated double bond in the molecule can be synthesized. Here, a method for synthesizing a modified polyphenylene ether compound of which the terminal is modified with a substituent having an unsaturated double bond will be described. Specific examples of the method include a method in which polyphenylene ether is reacted with a compound in which a substituent having an unsaturated double bond is bonded to a halogen atom.

Examples of the compound in which a substituent having an unsaturated double bond is bonded to a halogen atom include compounds in which substituents represented by Formulas (1) to (3) are bonded to a halogen atom. Specific examples of the halogen atom include a chlorine atom, a bromine atom, an iodine atom, and a fluorine atom. Among these, a chlorine atom is preferable. More specific examples of the compound in which a substituent having an unsaturated double bond is bonded to a halogen atom include o-chloromethylstyrene, p-chloromethylstyrene, and m-chloromethylstyrene. The compound in which a substituent having an unsaturated double bond is bonded to a halogen atom may be used singly or in combination of two or more kinds thereof. For example, o-chloromethylstyrene, p-chloromethylstyrene, and m-chloromethylstyrene may be used singly or in combination of two or three kinds thereof.

Polyphenylene ether which is a raw material is not particularly limited as long as a predetermined modified polyphenylene ether compound can be finally synthesized. Specific examples thereof include those containing polyphenylene ether containing 2,6-dimethylphenol and at least one of a bifunctional phenol and a trifunctional phenol and polyphenylene ether such as poly(2,6-dimethyl-1,4-phenylene oxide) as a main component. The bifunctional phenol is a phenol compound having two phenolic hydroxyl groups in the molecule, and examples thereof include tetramethyl bisphenol A. The trifunctional phenol is a phenol compound having three phenolic hydroxyl groups in the molecule.

Examples of the method for synthesizing the modified polyphenylene ether compound include the methods described above. Specifically, polyphenylene ether as described above and a compound in which a substituent having an unsaturated double bond is bonded to a halogen atom are dissolved in a solvent and stirred. By doing so, polyphenylene ether reacts with the compound in which a substituent having a carbon-carbon unsaturated double bond is bonded to a halogen atom, and the modified polyphenylene ether compound to be used in the present embodiment is obtained.

The reaction is preferably conducted in the presence of an alkali metal hydroxide. By doing so, it is considered that this reaction suitably proceeds. This is considered to be because the alkali metal hydroxide functions as a dehydrohalogenating agent, specifically, a dehydrochlorinating agent. In other words, it is considered that the alkali metal hydroxide eliminates the hydrogen halide from the phenol group in polyphenylene ether and the compound in which a substituent having a carbon-carbon unsaturated double bond is bonded to a halogen atom, and by doing so, the substituent having a carbon-carbon unsaturated double bond is bonded to the oxygen atom of the phenol group instead of the hydrogen atom of the phenol group in the polyphenylene ether.

The alkali metal hydroxide is not particularly limited as long as it can act as a dehalogenating agent, and examples thereof include sodium hydroxide. In addition, the alkali metal hydroxide is usually used in the form of an aqueous solution and is specifically used as an aqueous sodium hydroxide solution.

The reaction conditions such as reaction time and reaction temperature also vary depending on the compound in which a substituent having a carbon-carbon unsaturated double bond is bonded to a halogen atom and the like, and are not particularly limited as long as they are conditions under which the reaction as described above suitably proceeds. Specifically, the reaction temperature is preferably room temperature to 100° C. and more preferably 30° C. to 100° C. In addition, the reaction time is preferably 0.5 to 20 hours and more preferably 0.5 to 10 hours.

The solvent to be used at the time of the reaction is not particularly limited as long as it can dissolve polyphenylene ether and the compound in which a substituent having a carbon-carbon unsaturated double bond is bonded to a halogen atom, and does not inhibit the reaction of polyphenylene ether with the compound in which a substituent having a carbon-carbon unsaturated double bond is bonded to a halogen atom. Specific examples thereof include toluene.

The above reaction is preferably conducted in the presence of not only an alkali metal hydroxide but also a phase transfer catalyst. In other words, the above reaction is preferably conducted in the presence of an alkali metal hydroxide and a phase transfer catalyst. By doing so, it is considered that the above reaction more suitably proceeds. This is considered to be due to the following. This is considered to be because the phase transfer catalyst is a catalyst which has a function of taking in the alkali metal hydroxide, is soluble in both phases of a phase of a polar solvent such as water and a phase of a non-polar solvent such as an organic solvent, and can transfer between these phases. Specifically, in a case where an aqueous sodium hydroxide solution is used as an alkali metal hydroxide and an organic solvent, such as toluene, which is incompatible with water is used as a solvent, it is considered that when the aqueous sodium hydroxide solution is dropped into the solvent subjected to the reaction as well, the solvent and the aqueous sodium hydroxide solution are separated from each other and the sodium hydroxide is hardly transferred to the solvent. In that case, it is considered that the aqueous sodium hydroxide solution added as an alkali metal hydroxide hardly contributes to the promotion of the reaction. In contrast, when the reaction is conducted in the presence of an alkali metal hydroxide and a phase transfer catalyst, it is considered that the alkali metal hydroxide is transferred to the solvent in the state of being taken in the phase transfer catalyst and the aqueous sodium hydroxide solution is likely to contribute to the promotion of the reaction. For this reason, when the reaction is conducted in the presence of an alkali metal hydroxide and a phase transfer catalyst, it is considered that the above reaction more suitably proceeds.

The phase transfer catalyst is not particularly limited, and examples thereof include quaternary ammonium salts such as tetra-n-butylammonium bromide.

The resin composition to be used in the present embodiment preferably contains a modified polyphenylene ether compound obtained as described above as the polyphenylene ether compound.

(Curing Agent)

The curing agent is a curing agent capable of reacting with the polyphenylene ether compound and curing the resin composition containing the polyphenylene ether compound. The curing agent is not particularly limited as long as it is a curing agent capable of curing a resin composition containing the polyphenylene ether compound. Examples of the curing agent include styrene, styrene derivatives, a compound having an acryloyl group in the molecule, a compound having a methacryloyl group in the molecule, a compound having a vinyl group in the molecule, a compound having an allyl group in the molecule, a compound having an acenaphthylene structure in the molecule, a compound having a maleimide group in the molecule, and a compound having an isocyanurate group in the molecule.

Examples of the styrene derivatives include bromostyrene and dibromostyrene.

The compound having an acryloyl group in the molecule is an acrylate compound. Examples of the acrylate compound include a monofunctional acrylate compound having one acryloyl group in the molecule and a polyfunctional acrylate compound having two or more acryloyl groups in the molecule. Examples of the monofunctional acrylate compound include methyl acrylate, ethyl acrylate, propyl acrylate, and butyl acrylate. Examples of the polyfunctional acrylate compound include diacrylate compounds such as tricyclodecanedimethanol diacrylate.

The compound having a methacryloyl group in the molecule is a methacrylate compound. Examples of the methacrylate compound include a monofunctional methacrylate compound having one methacryloyl group in the molecule and a polyfunctional methacrylate compound having two or more methacryloyl groups in the molecule. Examples of the monofunctional methacrylate compound include methyl methacrylate, ethyl methacrylate, propyl methacrylate, and butyl methacrylate. Examples of the polyfunctional methacrylate compound include dimethacrylate compounds such as tricyclodecanedimethanol dimethacrylate.

The compound having a vinyl group in the molecule is a vinyl compound. Examples of the vinyl compound include a monofunctional vinyl compound (monovinyl compound) having one vinyl group in the molecule and a polyfunctional vinyl compound having two or more vinyl groups in the molecule. Examples of the polyfunctional vinyl compound include divinylbenzene and polybutadiene.

The compound having an allyl group in the molecule is an allyl compound. Examples of the allyl compound include a monofunctional allyl compound having one allyl group in the molecule and a polyfunctional allyl compound having two or more allyl groups in the molecule. Examples of the polyfunctional allyl compound include triallyl isocyanurate compounds such as triallyl isocyanurate (TAIC), diallyl bisphenol compounds, and diallyl phthalate (DAP).

The compound having an acenaphthylene structure in the molecule is an acenaphthylene compound. Examples of the acenaphthylene compound include acenaphthylene, alkylacenaphthylenes, halogenated acenaphthylenes, and phenylacenaphthylenes. Examples of the alkyl acenaphthylenes include 1-methyl acenaphthylene, 3-methyl acenaphthylene, 4-methyl acenaphthylene, 5-methyl acenaphthylene, 1-ethyl acenaphthylene, 3-ethyl acenaphthylene, 4-ethyl acenaphthylene, and 5-ethyl acenaphthylene. Examples of the halogenated acenaphthylenes include 1-chloroacenaphthylene, 3-chloroacenaphthylene, 4-chloroacenaphthylene, 5-chloroacenaphthylene, 1-bromoacenaphthylene, 3-bromoacenaphthylene, 4-bromoacenaphthylene, and 5-bromoacenaphthylene. Examples of the phenylacenaphthylenes include 1-phenylacenaphthylene, 3-phenylacenaphthylene, 4-phenylacenaphthylene, and 5-phenylacenaphthylene. The acenaphthylene compound may be a monofunctional acenaphthylene compound having one acenaphthylene structure in the molecule as described above or may be a polyfunctional acenaphthylene compound having two or more acenaphthylene structures in the molecule.

The compound having a maleimide group in the molecule is a maleimide compound. Examples of the maleimide compound include a monofunctional maleimide compound having one maleimide group in the molecule, a polyfunctional maleimide compound having two or more maleimide groups in the molecule, and a modified maleimide compound. Examples of the modified maleimide compound include a modified maleimide compound in which a part of the molecule is modified with an amine compound, a modified maleimide compound in which a part of the molecule is modified with a silicone compound, and a modified maleimide compound in which a part of the molecule is modified with an amine compound and a silicone compound.

The compound having an isocyanurate group in the molecule is an isocyanurate compound. Examples of the isocyanurate compound include a compound having an alkenyl group in the molecule (alkenyl isocyanurate compound), and examples thereof include a trialkenyl isocyanurate compound such as triallyl isocyanurate (TAIC).

Among the above, the curing agent is, for example, preferably the polyfunctional acrylate compound, the polyfunctional methacrylate compound, the polyfunctional vinyl compound, the styrene derivative, the allyl compound, the maleimide compound, the acenaphthylene compound, and the isocyanurate compound, and more preferably the allyl compound. As the allyl compound, an allyl isocyanurate compound having two or more allyl groups in the molecule is preferable, and triallyl isocyanurate (TAIC) is more preferable.

As the curing agent, the above curing agents may be used singly or in combination of two or more kinds thereof.

The weight average molecular weight of the curing agent is not particularly limited and is, for example, preferably 100 to 5000, more preferably 100 to 4000, still more preferably 100 to 3000. When the weight average molecular weight of the curing agent is too low, the curing agent may easily volatilize from the compounding component system of the resin composition. When the weight average molecular weight of the curing agent is too high, the viscosity of the varnish of the resin composition and the melt viscosity at the time of heat molding may be too high. Hence, a resin composition imparting superior heat resistance to the cured product is obtained when the weight average molecular weight of the curing agent is within such a range. It is considered that this is because the resin composition containing the polyphenylene ether compound can be suitably cured by the reaction of the curing agent with the polyphenylene ether compound. Here, the weight average molecular weight may be measured by a general molecular weight measurement method, and specific examples thereof include a value measured by gel permeation chromatography (GPC).

The average number (number of functional groups) of the functional groups which contribute to the reaction of the curing agent with the polyphenylene ether compound per one molecule of the curing agent varies depending on the weight average molecular weight of the curing agent, but is, for example, preferably 1 to 20, more preferably 2 to 18. When this number of functional groups is too small, sufficient heat resistance of the cured product tends to be hardly attained. When the number of functional groups is too large, the reactivity is too high and, for example, troubles such as a decrease in the storage stability of the resin composition or a decrease in the fluidity of the resin composition may occur.

(Boron Nitride)

The boron nitride is not particularly limited as long as it can be used as an inorganic filler contained in a resin composition. Examples of the boron nitride include a hexagonal normal-pressure phase (h-BN) and a cubic high-pressure phase (c-BN).

The average particle size of the boron nitride is preferably 0.5 to 11 μm, more preferably 2 to 5 μm. When the boron nitride is too small, there is a tendency that the thermal conductivity and heat resistance of the cured product of the obtained resin composition cannot be sufficiently increased. When the boron nitride is too large, there is a tendency that the moldability of the obtained resin composition decreases. Hence, when the average particle size of the boron nitride is within the above range, a resin composition to be a cured product having a high thermal conductivity and high heat resistance is more suitably obtained. Here, the average particle size refers to the volume average particle size. The volume average particle size can be measured by, for example, a laser diffraction method and the like.

The aspect ratio of the boron nitride is larger than the aspect ratio of the inorganic filler other than the boron nitride, and is, for example, preferably 1.5 to 10, more preferably 2 to 8. When the aspect ratio of the boron nitride is too small, there is a tendency that the thermal conductivity and heat resistance of the cured product of the obtained resin composition cannot be sufficiently increased. When the aspect ratio of the boron nitride is too large, there is a tendency that the moldability of the obtained resin composition decreases. Hence, when the aspect ratio of the boron nitride is within the above range, a resin composition to be a cured product having a high thermal conductivity and high heat resistance is more suitably obtained. Here, the aspect ratio indicates the average value of ratios (major axis/minor axis) of major axes to the minor axes. The major axis and minor axis can be measured, for example, by observing the boron nitride under a scanning electron microscope (SEM), and the aspect ratio can be calculated from the measured major axis and minor axis.

(Inorganic Filler Other than Boron Nitride)

The inorganic filler other than boron nitride is not particularly limited as long as it can be used as an inorganic filler contained in a resin composition and is an inorganic filler other than boron nitride. Examples of the inorganic filler other than boron nitride include metal oxides such as silica, alumina, titanium oxide, magnesium oxide and mica, metal hydroxides such as aluminum hydroxide and magnesium hydroxide, tale, aluminum borate, barium sulfate, aluminum nitride, magnesium carbonate such as anhydrous magnesium carbonate, and calcium carbonate. Among these, silica, anhydrous magnesium carbonate, alumina and the like are preferable as the inorganic filler other than boron nitride. The silica is not particularly limited, and examples thereof include crushed silica and silica particles, and silica particles are preferable. The magnesium carbonate is not particularly limited, but anhydrous magnesium carbonate (synthetic magnesite) is preferable.

The inorganic filler other than boron nitride may be an inorganic filler subjected to a surface treatment or an inorganic filler not subjected to a surface treatment. Examples of the surface treatment include treatment with a silane coupling agent.

Examples of the silane coupling agent include a silane coupling agent having at least one functional group selected from the group consisting of a vinyl group, a styryl group, a methacryloyl group, an acryloyl group, and a phenylamino group. In other words, examples of this silane coupling agent include compounds having at least one of a vinyl group, a styryl group, a methacryloyl group, an acryloyl group, or a phenylamino group as a reactive functional group, and further a hydrolyzable group such as a methoxy group or an ethoxy group.

Examples of the silane coupling agent include vinyltriethoxysilane and vinyltrimethoxysilane as those having a vinyl group. Examples of the silane coupling agent include p-styryltrimethoxysilane and p-styryltriethoxysilane as those having a styryl group. Examples of the silane coupling agent include 3-methacryloxypropyltrimethoxysilane, 3-methacryloxypropylmethyldimethoxysilane, 3-methacryloxypropyltriethoxysilane, 3-methacryloxypropylmethyldiethoxysilane, and 3-methacryloxypropylethyldiethoxysilane as those having a methacryloyl group. Examples of the silane coupling agent include 3-acryloxypropyltrimethoxysilane and 3-acryloxypropyltriethoxysilane as those having an acryloyl group. Examples of the silane coupling agent include N-phenyl-3-aminopropyltrimethoxysilane and N-phenyl-3-aminopropyltriethoxysilane as those having a phenylamino group.

The average particle size of the inorganic filler other than boron nitride is preferably 0.5 to 10 μm, more preferably 0.5 to 8 m. When the inorganic filler other than boron nitride is too small, there is a tendency that the heat resistance of the cured product of the obtained resin composition cannot be sufficiently enhanced. When the inorganic filler other than boron nitride is too large, there is a tendency that the heat resistance of the cured product of the obtained resin composition cannot be sufficiently enhanced. This is considered to be due to the following. First, it is considered that the difference in size between the inorganic filler other than boron nitride and the boron nitride becomes smaller and the inorganic filler other than boron nitride is less likely to exist between the boron nitrides. From this fact, it is considered that the effect of improving the heat resistance due to the existence of the inorganic filler other than boron nitride between the boron nitrides cannot be sufficiently exerted. Hence, when the average particle size of the inorganic filler other than boron nitride is within the above range, a resin composition to be a cured product having a high thermal conductivity and high heat resistance is more suitably obtained. Here, the average particle size refers to the volume average particle size. The volume average particle size can be measured by, for example, a laser diffraction method and the like.

The aspect ratio of the inorganic filler other than boron nitride is smaller than the aspect ratio of the boron nitride, and is, for example, preferably 1.2 or less, more preferably 1.1 or less. The aspect ratio of the inorganic filler other than boron nitride may be about 1, since there is a tendency that it is more preferable as the aspect ratio of the inorganic filler other than boron nitride is smaller. In other words, the aspect ratio of the inorganic filler other than boron nitride is preferably 1 to 1.2, more preferably 1 to 1.1. When the aspect ratio of the inorganic filler other than boron nitride is too large, there is a tendency that the heat resistance of the cured product of the obtained resin composition cannot be sufficiently enhanced. This is considered to be due to the following. First, it is considered that the shape of the inorganic filler other than boron nitride becomes distorted and the inorganic filler other than boron nitride is less likely to exist between the boron nitrides. From this fact, it is considered that the effect of improving the heat resistance due to the existence of the inorganic filler other than boron nitride between the boron nitrides cannot be sufficiently exerted. Hence, when the aspect ratio of the inorganic filler other than boron nitride is within the above range, a resin composition to be a cured product having a high thermal conductivity and high heat resistance is more suitably obtained. Here, the aspect ratio indicates the average value of ratios (major axis/minor axis) of major axes to the minor axes. The major axis and minor axis can be measured, for example, by observing the inorganic filler other than boron nitride under a scanning electron microscope (SEM), and the aspect ratio can be calculated from the measured major axis and minor axis. The inorganic filler other than boron nitride preferably has an aspect ratio of 1.2 or less as described above. In other words, it is preferable that the inorganic filler other than boron nitride has a spherical shape or a shape close to a spherical shape (for example, a cubic shape). From this point as well, the silica may be crushed silica or silica particles but silica particles are preferable as described above.

(Content)

As described above, the content of the boron nitride is 15 to 70 parts by volume, preferably 18 to 68 parts by volume, more preferably 20 to 65 parts by volume with respect to 100 parts by volume of the sum of the polyphenylene ether compound and the curing agent. As described above, the content of the inorganic filler other than boron nitride is preferably 5 to 30 parts by volume, more preferably 6 to 28 parts by volume, still more preferably 7 to 26 parts by volume with respect to 100 parts by volume of the sum of the polyphenylene ether compound and the curing agent. The ratio of the content of the boron nitride to the content of the inorganic filler other than boron nitride is preferably 3:2 (1.5:1) to 5:1, more preferably 2:1 to 5:1. By containing the boron nitride and the inorganic filler other than boron nitride in a resin composition containing the polyphenylene ether compound and the curing agent so as to satisfy the above content ranges, a resin composition to be a cured product exhibiting low dielectric properties, a high thermal conductivity, and high heat resistance is suitably obtained.

The content of the polyphenylene ether compound is preferably 60 to 90 parts by mass, more preferably 60 to 80 parts by mass with respect to 100 parts by mass of the sum of the polyphenylene ether compound and the curing agent. In other words, the content of the curing agent is preferably 10 to 40 parts by mass, more preferably 20 to 40 parts by mass with respect to 100 parts by mass of the sum of the polyphenylene ether compound and the curing agent. By containing each of the polyphenylene ether compound and the curing agent so as to satisfy the above content range in a resin composition containing the boron nitride and the inorganic filler other than boron nitride, a resin composition to be a cured product exhibiting low dielectric properties, a high thermal conductivity, and high heat resistance is suitably obtained.

(Other Components)

The resin composition according to the present embodiment may contain components (other components) other than the polyphenylene ether compound, the curing agent, and the inorganic filler (the boron nitride and the inorganic filler other than boron nitride) if necessary in a range in which the effects of the present invention are not impaired. As other components to be contained in the resin composition according to the present embodiment, for example, additives such as an elastomer, a silane coupling agent, an initiator, an antifoaming agent, an antioxidant, a heat stabilizer, an antistatic agent, an ultraviolet absorber, a dye or a pigment, and a lubricant may be further contained. The resin composition may contain thermosetting resins such as an epoxy resin, an unsaturated polyester resin, and a thermosetting polyimide resin in addition to the polyphenylene ether compound.

As described above, the resin composition according to the present embodiment may contain an elastomer. Examples of the elastomer include a styrene-based copolymer. Examples of the styrene-based copolymer include a methylstyrene (ethylene/butylene) methylstyrene copolymer, a methylstyrene (ethylene-ethylene/propylene) methylstyrene copolymer, a styrene isoprene copolymer, a styrene isoprene styrene copolymer, a styrene (ethylene/butylene) styrene copolymer, a styrene (ethylene-ethylene/propylene) styrene copolymer, a styrene butadiene styrene copolymer, a styrene (butadiene/butylene) styrene copolymer, a styrene isobutylene styrene copolymer, and hydrogenated products thereof. As the elastomer, those exemplified above may be used singly or in combination of two or more kinds thereof.

The content of the elastomer is preferably 5 to 30 parts by mass, more preferably 10 to 30 parts by mass with respect to 100 parts by mass of the sum of the polyphenylene ether compound, the curing agent, and the elastomer.

As described above, the resin composition according to the present embodiment may contain a silane coupling agent. The silane coupling agent may be contained in the resin composition or may be contained as a silane coupling agent covered on the inorganic filler contained in the resin composition for surface treatment in advance. Among these, it is preferable that the silane coupling agent is contained as a silane coupling agent covered on the inorganic filler for surface treatment in advance, and it is more preferable that the silane coupling agent is contained as a silane coupling agent covered on the inorganic filler for surface treatment in advance and further is also contained in the resin composition. In the case of a prepreg, the silane coupling agent may be contained in the prepreg as a silane coupling agent covered on the fibrous base material for surface treatment in advance. Examples of the silane coupling agent include those similar to the silane coupling agents used for the surface treatment of the inorganic filler other than boron nitride described above.

As described above, the resin composition according to the present embodiment may contain a flame retardant. The flame retardancy of a cured product of the resin composition can be enhanced by containing a flame retardant. The flame retardant is not particularly limited. Specifically, in the field in which halogen-based flame retardants such as bromine-based flame retardants are used, for example, ethylenedipentabromobenzene, ethylenebistetrabromoimide, decabromodiphenyloxide, and tetradecabromodiphenoxybenzene which have a melting point of 300° C. or more are preferable. It is considered that the elimination of halogen at a high temperature and the decrease in heat resistance can be suppressed by the use of a halogen-based flame retardant. In the field of being required to be free of halogen, a phosphoric ester-based flame retardant, a phosphazene-based flame retardant, a bis(diphenylphosphine oxide)-based flame retardant, and a phosphinate-based flame retardant are exemplified. Specific examples of the phosphoric ester-based flame retardant include a condensed phosphoric ester such as dixylenyl phosphate. Specific examples of the phosphazene-based flame retardant include phenoxyphosphazene. Specific examples of the bis(diphenylphosphine oxide)-based flame retardant include xylylenebis(diphenylphosphine oxide). Specific examples of the phosphinate-based flame retardant include metal phosphinates such as aluminum dialkyl phosphinate. As the flame retardant, the respective flame retardants exemplified may be used singly or in combination of two or more thereof.

As described above, the resin composition according to the present embodiment may contain an initiator (reaction initiator). The curing reaction can proceed even though the resin composition does not contain a reaction initiator. However, a reaction initiator may be added since there is a case where it is difficult to raise the temperature until curing proceeds depending on the process conditions. The reaction initiator is not particularly limited as long as it can promote the curing reaction of the polyphenylene ether compound with the curing agent. Specific examples thereof include oxidizing agents such as α,α′-bis(t-butylperoxy-m-isopropyl)benzene, 2,5-dimethyl-2,5-di(t-butylperoxy)-3-hexyne, benzoyl peroxide, 3,3′,5,5′-tetramethyl-1,4-diphenoquinone, chloranil, 2,4,6-tri-t-butylphenoxyl, t-butylperoxyisopropyl monocarbonate, and azobisisobutyronitrile. A metal carboxylate can be concurrently used if necessary. By doing so, the curing reaction can be further promoted. Among these, α,α′-bis(t-butylperoxy-m-isopropyl)benzene is preferably used. α,α′-Bis(t-butylperoxy-m-isopropyl)benzene has a relatively high reaction initiation temperature and thus can suppress the promotion of the curing reaction at the time point at which curing is not required, for example, at the time of prepreg drying, and can suppress a decrease in storage stability of the resin composition. α,α′-Bis(t-butylperoxy-m-isopropyl)benzene exhibits low volatility, thus does not volatilize at the time of prepreg drying and storage, and exhibits favorable stability. The reaction initiators may be used singly or in combination of two or more thereof.

(Production Method)

The method for producing the resin composition is not particularly limited, and examples thereof include a method in which the polyphenylene ether compound, the curing agent, the boron nitride, and the inorganic filler other than boron nitride are mixed together so as to have predetermined contents. Examples thereof include the method to be described later in the case of obtaining a varnish-like composition containing an organic solvent.

Moreover, by using the resin composition according to the present embodiment, a prepreg, a metal-clad laminate, a wiring board, a metal foil with resin, and a film with resin can be obtained as described below.

[Prepreg]

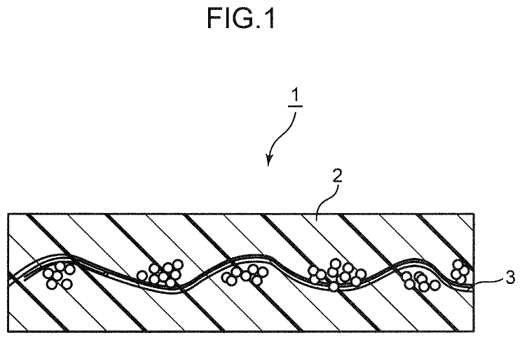

FIG. 1 is a schematic sectional view illustrating an example of a prepreg 1 according to an embodiment of the present invention.

As illustrated in FIG. 1, the prepreg 1 according to the present embodiment includes the resin composition or a semi-cured product 2 of the resin composition and a fibrous base material 3. This prepreg 1 includes the resin composition or the semi-cured product 2 of the resin composition and the fibrous base material 3 present in the resin composition or the semi-cured product 2 of the resin composition.

In the present embodiment, the semi-cured product is in a state in which the resin composition has been cured to an extent that the resin composition can be further cured. In other words, the semi-cured product is in a state in which the resin composition has been semi-cured (B-staged). For example, when the resin composition is heated, the viscosity gradually decreases at the beginning, then curing starts, and then the viscosity gradually increases. In such a case, the semi-cured state includes a state in which the viscosity has started to increase but curing is not completed, and the like.

The prepreg to be obtained using the resin composition according to the present embodiment may include a semi-cured product of the resin composition as described above or include the uncured resin composition itself. In other words, the prepreg may be a prepreg including a semi-cured product of the resin composition (the B-stage resin composition) and a fibrous base material or a prepreg including the resin composition before being cured (the A-stage resin composition) and a fibrous base material. The resin composition or a semi-cured product of the resin composition may be one obtained by drying or heating and drying the resin composition.

When a prepreg is manufactured, the resin composition 2 is often prepared in a varnish form and used in order to be impregnated into the fibrous base material 3 which is a base material for forming the prepreg. In other words, the resin composition 2 is usually a resin varnish prepared in a varnish form in many cases. Such a varnish-like resin composition (resin varnish) is prepared, for example, as follows.

First, the respective components which can be dissolved in an organic solvent are introduced into and dissolved in an organic solvent. At this time, heating may be performed if necessary. Thereafter, components which are used if necessary but are not dissolved in the organic solvent are added to and dispersed in the solution until a predetermined dispersion state is achieved using a ball mill, a bead mill, a planetary mixer, a roll mill or the like, whereby a varnish-like resin composition is prepared. The organic solvent used here is not particularly limited as long as it dissolves the polyphenylene ether compound, the curing agent, and the like, and does not inhibit the curing reaction. Specific examples thereof include toluene and methyl ethyl ketone (MEK).

Specific examples of the fibrous base material include glass cloth, aramid cloth, polyester cloth, a glass nonwoven fabric, an aramid nonwoven fabric, a polyester nonwoven fabric, pulp paper, and linter paper. When glass cloth is used, a laminate exhibiting excellent mechanical strength is obtained, and glass cloth subjected to flattening is particularly preferable. Specific examples of the flattening include a method in which glass cloth is continuously pressed at an appropriate pressure using a press roll to flatly compress the yarn. The thickness of the generally used fibrous base material is, for example, 0.01 mm or more and 0.3 mm or less. The glass fiber constituting the glass cloth is not particularly limited, and examples thereof include Q glass, NE glass, E glass, L glass, and L2 glass. The surface of the fibrous base material may be subjected to a surface treatment with a silane coupling agent. The silane coupling agent is not particularly limited, but examples thereof include a silane coupling agent having at least one selected from the group consisting of a vinyl group, an acryloyl group, a methacryloyl group, a styryl group, an amino group, and an epoxy group in the molecule.

The method for manufacturing the prepreg is not particularly limited as long as the prepreg can be manufactured. Specifically, when the prepreg is manufactured, the resin composition according to the present embodiment described above is often prepared in a varnish form and used as a resin varnish as described above.

Specific examples of the method for manufacturing the prepreg 1 include a method in which the fibrous base material 3 is impregnated with the resin composition 2, for example, the resin composition 2 prepared in a varnish form, and then dried. The fibrous base material 3 is impregnated with the resin composition 2 by dipping, coating, and the like. If necessary, the impregnation can be repeated a plurality of times. Moreover, at this time, it is also possible to finally adjust the composition and impregnated amount to the desired composition and impregnated amount by repeating impregnation using a plurality of resin compositions having different compositions and concentrations.

The fibrous base material 3 impregnated with the resin composition (resin varnish) 2 is heated under desired heating conditions, for example, at 80° C. or more and 180° C. or less for 1 minute or more and 10 minutes or less. By heating, the prepreg 1 before being cured (A-stage) or in a semi-cured state (B-stage) is obtained. By the heating, the organic solvent can be decreased or removed by being volatilized from the resin varnish.

The resin composition according to the present embodiment is a resin composition which provides a cured product exhibiting low dielectric properties, a high thermal conductivity, and high heat resistance. For this reason, the prepreg including this resin composition or a semi-cured product of this resin composition is a prepreg which provides a cured product exhibiting low dielectric properties, a high thermal conductivity, and high heat resistance. Moreover, a wiring board including an insulating layer containing a cured product exhibiting low dielectric properties, a high thermal conductivity, and high heat resistance can be suitably manufactured using this prepreg.

[Metal-Clad Laminate]

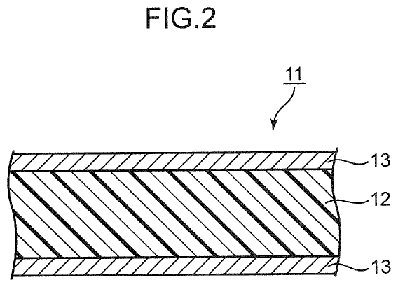

FIG. 2 is a schematic sectional view illustrating an example of a metal-clad laminate 11 according to an embodiment of the present invention.

As illustrated in FIG. 2, the metal-clad laminate 11 according to the present embodiment includes an insulating layer 12 containing a cured product of the resin composition and a metal foil 13 provided on the insulating layer 12. Examples of the metal-clad laminate 11 include a metal-clad laminate including an insulating layer 12 containing a cured product of the prepreg 1 illustrated in FIG. 1 and a metal foil 13 to be laminated together with the insulating layer 12. The insulating layer 12 may be formed of a cured product of the resin composition or a cured product of the prepreg. In addition, the thickness of the metal foil 13 varies depending on the performance and the like to be required for the finally obtained wiring board and is not particularly limited. The thickness of the metal foil 13 can be appropriately set depending on the desired purpose and is preferably, for example, 0.2 to 70 μm. Examples of the metal foil 13 include a copper foil and an aluminum foil, and the metal foil 13 may be a copper foil with carrier which includes a release layer and a carrier for the improvement in handleability in a case where the metal foil is thin.

The method for manufacturing the metal-clad laminate 11 is not particularly limited as long as the metal-clad laminate 11 can be manufactured. Specific examples thereof include a method in which the metal-clad laminate 11 is fabricated using the prepreg 1. Examples of this method include a method in which the double-sided metal foil-clad or single-sided metal foil-clad laminate 11 is fabricated by stacking one sheet or a plurality of sheets of prepreg 1, further stacking the metal foil 13 such as a copper foil on both or one of upper and lower surfaces of the prepregs 1, and laminating and integrating the metal foils 13 and prepregs 1 by heating and pressing. In other words, the metal-clad laminate 11 is obtained by laminating the metal foil 13 on the prepreg 1 and then performing heating and pressing. The heating and pressing conditions can be appropriately set depending on the thickness of the metal-clad laminate 11, the kind of the resin composition contained in the prepreg, and the like. For example, it is possible to set the temperature to 170° C. to 210° C., the pressure to 3 to 4 MPa, and the time to 60 to 150 minutes. Moreover, the metal-clad laminate may be manufactured without using a prepreg. Examples thereof include a method in which a varnish-like resin composition is applied on a metal foil to form a layer containing the resin composition on the metal foil and then heating and pressing is performed.

The resin composition according to the present embodiment is a resin composition which provides a cured product exhibiting low dielectric properties, a high thermal conductivity, and high heat resistance. For this reason, the metal-clad laminate including an insulating layer containing the cured product of this resin composition is a metal-clad laminate including an insulating layer containing a cured product exhibiting low dielectric properties, a high thermal conductivity, and high heat resistance. Moreover, a wiring board including an insulating layer containing a cured product exhibiting low dielectric properties, a high thermal conductivity, and high heat resistance can be suitably manufactured using this metal-clad laminate.

[Wiring Board]

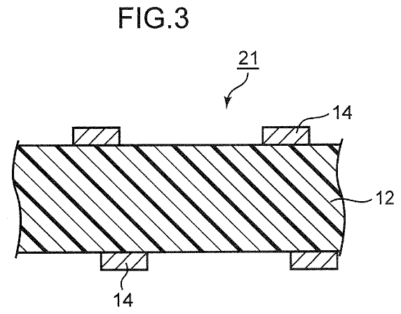

FIG. 3 is a schematic sectional view illustrating an example of a wiring board 21 according to an embodiment of the present invention.

As illustrated in FIG. 3, the wiring board 21 according to the present embodiment includes an insulating layer 12 containing a cured product of the resin composition and wiring 14 provided on the insulating layer 12. Examples of the wiring board 21 include a wiring board formed of an insulating layer 12 obtained by curing the prepreg 1 illustrated in FIG. 1 and wiring 14 which is laminated together with the insulating layer 12 and is formed by partially removing the metal foil 13. The insulating layer 12 may be formed of a cured product of the resin composition or a cured product of the prepreg.

The method for manufacturing the wiring board 21 is not particularly limited as long as the wiring board 21 can be manufactured. Specific examples thereof include a method in which the wiring board 21 is fabricated using the prepreg 1. Examples of this method include a method in which the wiring board 21, in which wiring is provided as a circuit on the surface of the insulating layer 12, is fabricated by forming wiring through etching and the like of the metal foil 13 on the surface of the metal-clad laminate 11 fabricated in the manner described above. In other words, the wiring board 21 is obtained by partially removing the metal foil 13 on the surface of the metal-clad laminate 11 and thus forming a circuit. Examples of the method for forming a circuit include circuit formation by a semi-additive process (SAP) or a modified semi-additive process (MSAP) in addition to the method described above. The wiring board 21 is a wiring board including an insulating layer 12 containing a cured product exhibiting low dielectric properties, a high thermal conductivity, and high heat resistance.

[Metal Foil with Resin]

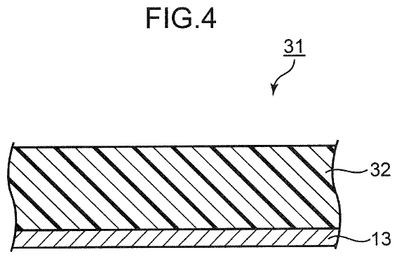

FIG. 4 is a schematic sectional view illustrating an example of a metal foil with resin 31 according to the present embodiment.

The metal foil with resin 31 according to the present embodiment includes a resin layer 32 containing the resin composition or a semi-cured product of the resin composition and a metal foil 13 as illustrated in FIG. 4. The metal foil with resin 31 includes the metal foil 13 on the surface of the resin layer 32. In other words, the metal foil with resin 31 includes the resin layer 32 and the metal foil 13 to be laminated together with the resin layer 32. The metal foil with resin 31 may include other layers between the resin layer 32 and the metal foil 13.

The resin layer 32 may contain a semi-cured product of the resin composition as described above or may contain the uncured resin composition. In other words, the metal foil with resin 31 may be a metal foil with resin including a resin layer containing a semi-cured product of the resin composition (the B-stage resin composition) and a metal foil or a metal foil with resin including a resin layer containing the resin composition before being cured (the A-stage resin composition) and a metal foil. The resin layer is only required to contain the resin composition or a semi-cured product of the resin composition and may or may not contain a fibrous base material. The resin composition or a semi-cured product of the resin composition may be one obtained by drying or heating and drying the resin composition. As the fibrous base material, those similar to the fibrous base materials of the prepreg can be used.

As the metal foil, metal foils to be used in metal-clad laminates or metal foils with resin can be used without limitation. Examples of the metal foil include a copper foil and an aluminum foil.

The metal foil with resin 31 may include a cover film and the like if necessary. By including a cover film, it is possible to prevent entry of foreign matter and the like. The cover film is not particularly limited, and examples thereof include a polyolefin film, a polyester film, a polymethylpentene film, and films formed by providing a release agent layer on these films.

The method for manufacturing the metal foil with resin 31 is not particularly limited as long as the metal foil with resin 31 can be manufactured. Examples of the method for manufacturing the metal foil with resin 31 include a method in which the varnish-like resin composition (resin varnish) is applied on the metal foil 13 and heated to manufacture the metal foil with resin 31. The varnish-like resin composition is applied on the metal foil 13 using, for example, a bar coater. The applied resin composition is heated under the conditions of, for example, 80° C. or more and 180° C. or less and 1 minute or more and 10 minutes or less. The heated resin composition is formed as the uncured resin layer 32 on the metal foil 13. By the heating, the organic solvent can be decreased or removed by being volatilized from the resin varnish.

The resin composition according to the present embodiment is a resin composition which provides a cured product exhibiting low dielectric properties, a high thermal conductivity, and high heat resistance. For this reason, the metal foil with resin including a resin layer containing this resin composition or a semi-cured product of this resin composition is a metal foil with resin including a resin layer, which provides a cured product exhibiting low dielectric properties, a high thermal conductivity, and high heat resistance. Moreover, this metal foil with resin can be used when a wiring board including an insulating layer containing a cured product exhibiting low dielectric properties, a high thermal conductivity, and high heat resistance is manufactured. For example, by laminating the metal foil with resin on a wiring board, a multilayer wiring board can be manufactured. As the wiring board obtained by using such a metal foil with resin, a wiring board including an insulating layer containing a cured product exhibiting low dielectric properties, a high thermal conductivity, and high heat resistance is obtained.

[Film with Resin]

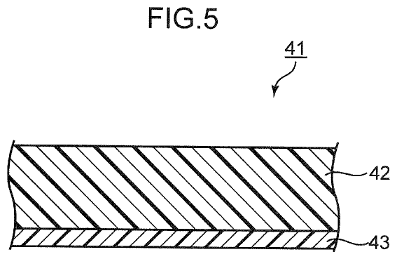

FIG. 5 is a schematic sectional view illustrating an example of a film with resin 41 according to the present embodiment.

The film with resin 41 according to the present embodiment includes a resin layer 42 containing the resin composition or a semi-cured product of the resin composition and a support film 43 as illustrated in FIG. 5. The film with resin 41 includes the resin layer 42 and the support film 43 to be laminated together with the resin layer 42. The film with resin 41 may include other layers between the resin layer 42 and the support film 43.

The resin layer 42 may contain a semi-cured product of the resin composition as described above or may contain the uncured resin composition. In other words, the film with resin 41 may be a film with resin including a resin layer containing a semi-cured product of the resin composition (the B-stage resin composition) and a support film or a film with resin including a resin layer containing the resin composition before being cured (the A-stage resin composition) and a support film. The resin layer is only required to contain the resin composition or a semi-cured product of the resin composition and may or may not contain a fibrous base material. The resin composition or a semi-cured product of the resin composition may be one obtained by drying or heating and drying the resin composition. As the fibrous base material, those similar to the fibrous base materials of the prepreg can be used.

As the support film 43, support films to be used in films with resin can be used without limitation. Examples of the support film include electrically insulating films such as a polyester film, a polyethylene terephthalate (PET) film, a polyimide film, a polyparabanic acid film, a polyether ether ketone film, a polyphenylene sulfide film, a polyamide film, a polycarbonate film, and a polyarylate film.

The film with resin 41 may include a cover film and the like if necessary. By including a cover film, it is possible to prevent entry of foreign matter and the like. The cover film is not particularly limited, and examples thereof include a polyolefin film, a polyester film, and a polymethylpentene film.

The support film and the cover film may be those subjected to surface treatments such as a matt treatment, a corona treatment, a release treatment, and a roughening treatment if necessary.

The method for manufacturing the film with resin 41 is not particularly limited as long as the film with resin 41 can be manufactured. Examples of the method for manufacturing the film with resin 41 include a method in which the varnish-like resin composition (resin varnish) is applied on the support film 43 and heated to manufacture the film with resin 41. The varnish-like resin composition is applied on the support film 43 using, for example, a bar coater. The applied resin composition is heated under the conditions of, for example, 80° C. or more and 180° C. or less and 1 minute or more and 10 minutes or less. The heated resin composition is formed as the uncured resin layer 42 on the support film 43. By the heating, the organic solvent can be decreased or removed by being volatilized from the resin varnish.

The resin composition according to the present embodiment is a resin composition which provides a cured product exhibiting low dielectric properties, a high thermal conductivity, and high heat resistance. For this reason, the film with resin including a resin layer containing this resin composition or a semi-cured product of this resin composition is a film with resin including a resin layer, which provides a cured product exhibiting low dielectric properties, a high thermal conductivity, and high heat resistance. Moreover, this film with resin can be used when a wiring board including an insulating layer containing a cured product exhibiting low dielectric properties, a high thermal conductivity, and high heat resistance is suitably manufactured. A multilayer wiring board can be manufactured, for example, by laminating the film with resin on a wiring board and then peeling off the support film from the film with resin or by peeling off the support film from the film with resin and then laminating the film with resin on a wiring board. As the wiring board obtained by using such a film with resin, a wiring board including an insulating layer containing a cured product exhibiting low dielectric properties, a high thermal conductivity, and high heat resistance is obtained.

The present specification discloses various aspects of a technique as described above, but the main technique is summarized below.

An aspect of the present invention is a resin composition containing a polyphenylene ether compound, a curing agent, boron nitride, and an inorganic filler other than boron nitride, in which the content of boron nitride is 15 to 70 parts by volume with respect to 100 parts by volume of a sum of the polyphenylene ether compound and the curing agent.

According to such a configuration, it is possible to provide a resin composition, which provides a cured product exhibiting low dielectric properties, a high thermal conductivity, and high heat resistance.

This is considered to be due to the following.

First, it is considered that a cured product which maintains the excellent low dielectric properties of polyphenylene ether is obtained by curing the polyphenylene ether compound together with the curing agent even when boron nitride and an inorganic filler other than the boron nitride are contained in the resin composition. It is considered that a cured product having a high thermal conductivity is obtained since the resin composition contains a predetermined amount of boron nitride exhibiting high thermal conductivity. It is considered that an inorganic filler other than the boron nitride is contained so as to exist between the boron nitrides by containing not only the boron nitride but also the inorganic filler other than the boron nitride in the resin composition. For this reason, it is considered that the resin composition provides a cured product exhibiting high heat resistance as well as a high thermal conductivity. From the above facts, it is considered that the resin composition provides a cured product exhibiting low dielectric properties, a high thermal conductivity, and high heat resistance.

In the resin composition, it is preferable that the inorganic filler other than boron nitride includes at least one selected from the group consisting of silica, anhydrous magnesium carbonate, and alumina.

According to such a configuration, a resin composition to be a cured product exhibiting low dielectric properties, a high thermal conductivity, and high heat resistance is obtained. It is considered that this is because the inorganic filler other than boron nitride has a shape different from that of the boron nitride and thus the inorganic filler other than boron nitride suitably exists between the boron nitrides.

In the resin composition, it is preferable that the polyphenylene ether compound includes a polyphenylene ether compound having at least one of a group represented by the following Formula (1) and a group represented by the following Formula (2) in the molecule.

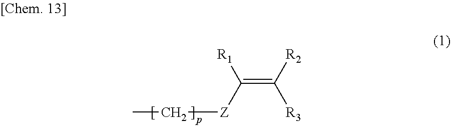

In Formula (1), p represents 0 to 10, Z represents an arylene group, and R₁ to R₃ each independently represent a hydrogen atom or an alkyl group.

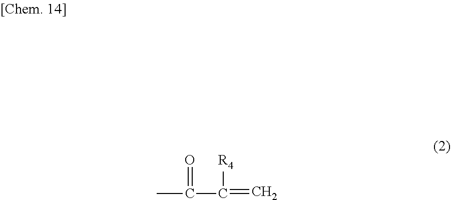

In Formula (2), R₄ represents a hydrogen atom or an alkyl group.

According to such a configuration, a resin composition to be a cured product exhibiting low dielectric properties, a high thermal conductivity, and high heat resistance is obtained. It is considered that this is because the polyphenylene ether compound is more suitably cured together with the curing agent.

In the resin composition, it is preferable that the content of the inorganic filler other than boron nitride is 5 to 30 parts by volume with respect to 100 parts by volume of the sum of the polyphenylene ether compound and the curing agent.

According to such a configuration, a resin composition to be a cured product exhibiting low dielectric properties, a high thermal conductivity, and high heat resistance is obtained. It is considered that this is because the inorganic filler other than boron nitride can suitably increase the thermal conductivity and heat resistance of the cured product.

In the resin composition, it is preferable that the ratio of the content of boron nitride to the content of the inorganic filler other than boron nitride is 3:2 to 5:1 as a volume ratio.

According to such a configuration, a resin composition to be a cured product exhibiting low dielectric properties, a high thermal conductivity, and high heat resistance is obtained. It is considered that this is because the boron nitride and the inorganic filler other than boron nitride can suitably increase the thermal conductivity and heat resistance of the cured product.

In the resin composition, it is preferable that the cured product of the resin composition has a thermal conductivity of 1 W/m·K or more and a relative dielectric constant of 3.7 or less at a frequency of 10 GHz.

According to such a configuration, the resin composition is a resin composition which provides a cured product having a relative dielectric constant of 3.7 or less, namely, low dielectric properties, and a high thermal conductivity of 1 W/m·K or more.

Another aspect of the present invention is a prepreg including the resin composition or a semi-cured product of the resin composition, and a fibrous base material.

According to such a configuration, it is possible to provide a prepreg, which provides a cured product exhibiting low dielectric properties, a high thermal conductivity, and high heat resistance.

Another aspect of the present invention is a film with resin including a resin layer containing the resin composition or a semi-cured product of the resin composition, and a support film.

According to such a configuration, it is possible to provide a film with resin including a resin layer, which provides a cured product exhibiting low dielectric properties, a high thermal conductivity, and high heat resistance.

Another aspect of the present invention is a metal foil with resin including a resin layer containing the resin composition or a semi-cured product of the resin composition, and a metal foil.

According to such a configuration, it is possible to provide a metal foil with resin including a resin layer, which provides a cured product exhibiting low dielectric properties, a high thermal conductivity, and high heat resistance.

Another aspect of the present invention is a metal-clad laminate including an insulating layer containing a cured product of the resin composition or a cured product of the prepreg, and a metal foil.

According to such a configuration, it is possible to provide a metal-clad laminate including an insulating layer containing a cured product exhibiting low dielectric properties, a high thermal conductivity, and high heat resistance.

Another aspect of the present invention is a wiring board including an insulating layer containing a cured product of the resin composition or a cured product of the prepreg, and wiring.

According to such a configuration, it is possible to provide a metal-clad laminate including an insulating layer containing a cured product exhibiting low dielectric properties, a high thermal conductivity, and high heat resistance.

According to the present invention, it is possible to provide a resin composition, which provides a cured product exhibiting low dielectric properties, a high thermal conductivity, and high heat resistance. In addition, according to the present invention, a prepreg, a film with resin, a metal foil with resin, a metal-clad laminate, and a wiring board which are obtained using the resin composition are provided.

Hereinafter, the present invention will be described more specifically with reference to examples, but the scope of the present invention is not limited thereto.

### EXAMPLES

### Examples 1 to 10 and Comparative Examples 1 to 8

The respective components to be used when preparing a resin composition in the present examples will be described. The specific gravity of each component is the specific gravity when pure water is used as a reference substance.

(Polyphenylene Ether Compound)

PPE: Polyphenylene ether compound having a methacryloyl group at the terminal (modified polyphenylene ether obtained by modifying the terminal hydroxyl groups of polyphenylene ether with a methacryloyl group, a modified polyphenylene ether compound represented by Formula (12), where Y is a dimethylmethylene group (a group represented by Formula (9), where R₃₃ and R₃₄ are a methyl group), SA9000 manufactured by SABIC Innovative Plastics, weight average molecular weight Mw: 2000, number of terminal functional groups: 2, specific gravity: 1.1)

(Curing Agent)

TAIC: Triallyl isocyanurate (TAIC manufactured by Nihon Kasei CO., LTD., specific gravity: 1.1)

(Initiator)

PBP: PBP: α,α′-Di(t-butylperoxy)diisopropylbenzene (Perbutyl P (PBP) manufactured by NOF CORPORATION, specific gravity: 0.9)

(Elastomer)

V9827: Hydrogenated methylstyrene (ethylene/butylene) methylstyrene copolymer (SEPTON V9827 manufactured by Kuraray Co., Ltd., specific gravity: 0.9)

Ricon100: Butadiene-styrene oligomer (Ricon 100 manufactured by CRAY VALLEY)

(Boron Nitride)

Boron nitride: AP-10S (manufactured by MARUKA CORPORATION., LTD., volume average particle size: 3.0 μm, average aspect ratio: 4.7, specific gravity: 2.3)

(Inorganic Filler Other than Boron Nitride)

Synthetic magnesite: Anhydrous magnesium carbonate particles (MAGTHERMO MS-L manufactured by Konoshima Chemical Co., Ltd., volume average particle size: 8 μm, average aspect ratio: 1.0, specific gravity: 3.0)

SC2300SVJ: Silica particles subjected to a surface treatment with a silane coupling agent having a vinyl group in the molecule (SC2300SVJ manufactured by Admatechs Company Limited, volume average particle size: 0.5 μm, average aspect ratio: 1.0, specific gravity: 2.2)

Alumina: Alumina particles (DAW-03AC manufactured by Denka Company Limited, volume average particle size: 3.7 μm, average aspect ratio: 1.0, specific gravity: 3.8)

[Preparation Method]

First, the respective components other than the inorganic filler (boron nitride and the inorganic filler other than boron nitride) were added to and mixed in methyl ethyl ketone (MEK) at the composition (parts by mass) presented in Table 1 so that the solid concentration was 70% by mass. The mixture was stirred for 60 minutes. Thereafter, the filler was added to the obtained liquid, and the inorganic filler was dispersed in the liquid using a bead mill. By doing so, a varnish-like resin composition (varnish) was obtained.

Next, an evaluation substrate (cured product of prepreg) was obtained as follows.

The obtained varnish was impregnated into a fibrous base material (glass cloth: #1078 type, L Glass manufactured by Asahi Kasei Corporation) and then heated and dried at 130° C. for 3 minutes, thereby fabricating a prepreg. At that time, the content (resin content) of the components constituting the resin with respect to the prepreg was adjusted to be the value (% by volume, % by mass) presented in Table 1 by the curing reaction. Thereafter, two sheets of each obtained prepreg were stacked and heated to a temperature of 200° C. at a rate of temperature rise of 4° C./min and heated and pressed under the conditions of 200° C., 120 minutes, and a pressure of 4 MPa, thereby obtaining an evaluation substrate (cured product of prepreg).

The prepregs and evaluation substrates (cured products of prepregs) prepared as described above were evaluated by the methods described below.

[Dielectric Properties (Relative Dielectric Constant)]

The relative dielectric constant of the evaluation substrate (cured product of prepreg) at 10 GHz was measured by the cavity resonator perturbation method. Specifically, the relative dielectric constant of the evaluation substrate at 10 GHz was measured using a network analyzer (N5230A manufactured by Keysight Technologies).

(PCT Solder Heat Resistance)

The PCT solder heat resistance was measured by the following method. First, the obtained evaluation substrate (cured product of prepreg) was cut into a size of 50 mm in length and 50 mm in width, and this cut substrate was used as a test sample. This test sample was placed in a pressure cooker testing machine at 121° C., 2 atm (0.2 MPa), and a relative humidity of 100% for 6 hours. In other words, the test sample was subjected to a pressure cooker test (PCT) at 121° C., 2 atm (0.2 MPa), and a relative humidity of 100% for 6 hours. The test sample subjected to PCT was immersed in a solder bath at 288° C. for 20 seconds. Thereafter, the immersed test sample was visually observed to confirm the occurrence of swelling.

Separately, the pressure cooker test (PCT) was performed on the test sample by changing the conditions of the pressure cooker test (PCT) from 121° C. to 133° C. The test sample subjected to PCT was immersed in a solder bath at 288° C. for 20 seconds. Thereafter, the immersed test sample was visually observed to confirm the occurrence of swelling.

As a result, it was evaluated as “Very Good” when the occurrence of swelling was not confirmed even in a case where PCT at 133° C. was performed. It was evaluated as “Good” when the occurrence of swelling was confirmed in a case where PCT at 133° C. was performed but the occurrence of swelling was not confirmed in a case where PCT at 121° C. was performed. It was evaluated as “Poor” when the occurrence of swelling was confirmed in a case where PCT at 121° C. was performed.

(Thermal Conductivity)

The thermal conductivity of the obtained evaluation substrate (cured product of prepreg) was measured by a method conforming to ASTM D5470. Specifically, the thermal conductivity of the obtained evaluation substrate (cured product of prepreg) was measured using a thermal property evaluating instrument (T3Ster DynTIM Tester manufactured by Mentor Graphics Corporation).

The results of each of the evaluations are presented in Table 1.

TABLE 1

| | | | Example | | | | | | | Comparative Example | | | | | | | |
|---|---|---|---|---|---|---|---|---|---|---|---|---|---|---|---|---|---|
| | | | 1 | 2 | 3 | 4 | 5 | 6 | 7 | 1 | 2 | 3 | 4 | 5 | 6 | 7 | 8 |
| Compo- | PPE | | 70 | 70 | 70 | 70 | 57 | 70 | 60 | 70 | 70 | 100 | — | 70 | 70 | 70 | 70 |
| sition | Curing agent | TAIC | 30 | 30 | 30 | 30 | 28 | 30 | 40 | 30 | 30 | — | 30 | 30 | 30 | 30 | 30 |
| (parts by | Initiator | PBP | 1 | 1 | 1 | 1 | 1 | 1 | 1 | 1 | 1 | 1 | 1 | 1 | 1 | 1 | 1 |
| mass) | Elastomer | V9827 | — | — | — | — | 15 | — | — | — | — | — | — | — | — | — | — |
| | | Ricon100 | — | — | — | — | — | — | — | — | — | — | 70 | — | — | — | — |
| | Boron nitride | | 42 | 80 | 75 | 80 | 80 | 75 | 80 | 26 | 188 | 80 | 80 | 70 | — | — | — |
| | Inorganic | Synthetic | — | — | 20 | 43 | — | — | 43 | — | — | — | — | — | 92 | — | — |
| | filler other | magnesite | | | | | | | | | | | | | | | |
| | than boron | SC2300SVJ | 27 | 31 | — | — | 31 | — | — | 25 | 20 | 31 | 31 | — | — | 67 | — |
| | nitride | Alumina | — | — | — | — | — | 25 | — | — | — | — | — | — | — | — | 115 |
| Compo- | Sum of PPE and | | 75 | 65 | 70 | 65 | 53 | 70 | 65 | 80 | 50 | 65 | 17 | 75 | 75 | 75 | 75 |
| sition | curing agent | | | | | | | | | | | | | | | | |
| (parts by | Boron nitride | | 15 | 25 | 25 | 25 | 25 | 25 | 25 | 10 | 45 | 25 | 25 | 25 | — | — | — |
| volume) | Inorganic | Synthetic | — | — | 5 | 10 | — | — | 10 | — | — | — | — | — | 25 | — | — |
| | filler other | magnesite | | | | | | | | | | | | | | | |
| | than boron | SC2300SVJ | 10 | 10 | — | — | 10 | — | — | 10 | 5 | 10 | 10 | — | — | 25 | — |
| | nitride | Alumina | — | — | — | — | — | 5 | — | — | — | — | — | — | — | — | 25 |

| Sum of boron nitride and filler | | 25 | 35 | 30 | 35 | 35 | 30 | 35 | 20 | 50 | 35 | 35 | 25 | 25 | 25 | 25 |
|---|---|---|---|---|---|---|---|---|---|---|---|---|---|---|---|---|
| other than boron nitride | | | | | | | | | | | | | | | | |
| (parts by volume) | | | | | | | | | | | | | | | | |
| Content of boron nitride with respect | | 20 | 38 | 36 | 38 | 47 | 36 | 38 | 13 | 90 | 38 | 147 | 33 | 0 | 0 | 0 |
| to 100 parts by volume of sum of PPE | | | | | | | | | | | | | | | | |
| and curing agent (parts by volume) | | | | | | | | | | | | | | | | |
| Content of boron nitride with respect | | 13 | 15 | 7 | 15 | 19 | 7 | 15 | 13 | 10 | 15 | 59 | 0 | 33 | 33 | 33 |
| to 100 parts by volume of sum of PPE | | | | | | | | | | | | | | | | |
| and curing agent (parts by volume) | | | | | | | | | | | | | | | | |
| Boron nitride: filler other than | | 1.5:1 | 2.5:1 | 5.0:1 | 2.5:1 | 2.5:1 | 5.0:1 | 2.5:1 | 1.0:1 | 9.0:1 | 2.5:1 | 2.5:1 | — | — | — | — |
| boron nitride (volume ratio) | | | | | | | | | | | | | | | | |
| Resin content (% by volume) | | 84.1 | 84.1 | 84.1 | 84.1 | 84.1 | 84.1 | 84.1 | 84.1 | 84.1 | 84.1 | 84.1 | 84.1 | 84.1 | 84.1 | 84.1 |
| Resin content (% by mass) | | 76.2 | 77.6 | 77.6 | 78.5 | 77.6 | 78.0 | 78.5 | 75.4 | 79.6 | 77.6 | 76.3 | 76.3 | 78.5 | 76.1 | 80.4 |
| Result | Relative dielectric constant | 3.1 | 3.3 | 3.4 | 3.5 | 3.3 | 3.5 | 3.5 | 3.0 | 3.6 | 3.1 | 3.1 | 3.3 | 3.5 | 3.1 | 4.2 |
| | PCT solder heat resistance | Very | Good | Good | Good | Very | Good | Good | Very | Poor | Poor | Poor | Poor | Very | Very | Good |
| | | Good | | | | Good | | | Good | | | | | Good | Good | |
| | Thermal conductivity | 1.0 | 1.3 | 1.4 | 1.5 | 1.2 | 1.4 | 1.5 | 0.8 | 1.9 | 1.2 | 1.1 | 1.2 | 0.8 | 0.5 | 0.9 |
| | (W/m · K) | | | | | | | | | | | | | | | |

As can be seen from Table 1, in a resin composition containing a polyphenylene ether compound, a curing agent, boron nitride, and an inorganic filler other than the boron nitride, in a case where the content of the boron nitride is 15 to 70 parts by volume with respect to 100 parts by volume of the sum of the polyphenylene ether compound and the curing agent (Examples 1 to 7), a cured product having a low relative dielectric constant, high PCT heat resistance, and a high thermal conductivity was obtained. More specifically, in the resin compositions according to Examples 1 to 7, the thermal conductivity of the cured products was higher as compared with that in a case where the content of the boron nitride is less than 15 parts by volume with respect to 100 parts by volume of the sum of the polyphenylene ether compound and the curing agent (Comparative Examples 1 and 6 to 8). In the resin compositions according to Examples 1 to 7, the PCT heat resistance of the cured products was higher as compared with that in a case where the content of the boron nitride is more than 70 parts by volume with respect to 100 parts by volume of the sum of the polyphenylene ether compound and the curing agent (Comparative Example 2), a case where a curing agent was not contained (Comparative Example 3), a case where PPE was not contained (but an elastomer was contained instead of PPE) (Comparative Example 4), and a case where an inorganic filler other than boron nitride was not contained (Comparative Example 5). From these facts, it has been found that a cured product exhibiting low dielectric properties, a high thermal conductivity, and high heat resistance is obtained in a case where the content of the boron nitride is 15 to 70 parts by volume with respect to 100 parts by volume of the sum of the polyphenylene ether compound and the curing agent in a resin composition containing a polyphenylene ether compound, a curing agent, boron nitride, and an inorganic filler other than the boron nitride (Examples 1 to 7).

This application is based on Japanese Patent Application No. 2019-176538 filed on Sep. 27, 2019, the contents of which are included in the present application.

In order to express the present invention, the present invention has been described above appropriately and sufficiently through the embodiments. However, it should be recognized by those skilled in the art that changes and/or improvements of the above-described embodiments can be readily made. Accordingly, changes or improvements made by those skilled in the art shall be construed as being included in the scope of the claims unless otherwise the changes or improvements are at the level which departs from the scope of the appended claims.

### INDUSTRIAL APPLICABILITY

According to the present invention, there is provided a resin composition, which provides a cured product exhibiting low dielectric properties, a high thermal conductivity, and high heat resistance. In addition, according to the present invention, a prepreg, a film with resin, a metal foil with resin, a metal-clad laminate, and a wiring board which are obtained using the resin composition are provided.

1. A resin composition comprising:
a polyphenylene ether compound;
a curing agent;
boron nitride; and
an inorganic filler other than the boron nitride,
wherein a content of boron nitride is 15 to 70 parts by volume with respect to 100 parts by volume of a sum of the polyphenylene ether compound and the curing agent.

2. The resin composition according to claim 1, wherein the inorganic filler other than the boron nitride includes at least one selected from the group consisting of silica, anhydrous magnesium carbonate, and alumina.

3. The resin composition according to claim 1, wherein the polyphenylene ether compound includes a polyphenylene ether compound having at least one of a group represented by the following Formula (1) and a group represented by the following Formula (2) in a molecule: 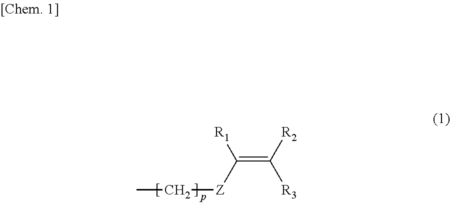
[in Formula (1), p represents 0 to 10, Z represents an arylene group, and R₁ to R₃ each independently represent a hydrogen atom or an alkyl group] 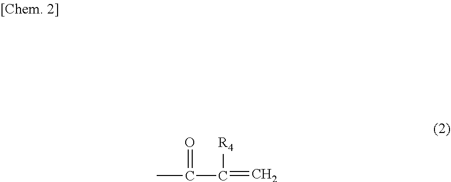
[in Formula (2), R₄ represents a hydrogen atom or an alkyl group].

4. The resin composition according to claim 1, wherein a content of the inorganic filler other than the boron nitride is 5 to 30 parts by volume with respect to 100 parts by volume of a sum of the polyphenylene ether compound and the curing agent.

5. The resin composition according to claim 1, wherein a ratio of the content of the boron nitride to the content of the inorganic filler other than the boron nitride is 3:2 to 5:1 as a volume ratio.

6. The resin composition according to claim 1, wherein a cured product of the resin composition has a thermal conductivity of 1 W/m·K or more and a relative dielectric constant of 3.7 or less at a frequency of 10 GHz.

7. A prepreg comprising:
the resin composition according to claim 1 or a semi-cured product of the resin composition; and
a fibrous base material.

8. A film with resin comprising:
a resin layer containing the resin composition according to claim 1 or a semi-cured product of the resin composition; and
a support film.

9. A metal foil with resin comprising:
a resin layer containing the resin composition according to claim 1 or a semi-cured product of the resin composition; and
a metal foil.

10. A metal-clad laminate comprising:
an insulating layer containing a cured product of the resin composition according to claim 1; and
a metal foil.

11. A wiring board comprising:
an insulating layer containing a cured product of the resin composition according to claim 1; and
wiring.

12. A metal-clad laminate comprising:
an insulating layer containing a cured product of the prepreg according to claim 7; and
a metal foil.

13. A wiring board comprising:
an insulating layer containing a cured product of the prepreg according to claim 7; and
wiring.
